(19) United States
(12) Patent Application Publication
(10) Pub. No.: US 2025/0280516 A1
(43) Pub. Date: Sep. 4, 2025

(54) BLOCK CHAIN SERVER AND POWER SUPPLY HEAT SINKING METHOD AND APPARATUS THEREOF, AND POWER SUPPLY, AND STORAGE MEDIUM

(71) Applicant: SHENZHEN MICROBT ELECTRONICS TECHNOLOGY CO., LTD., Nanshan District Shenzhen, Guangdong (CN)

(72) Inventors: Yang GAO, Nanshan District Shenzhen, Guangdong (CN); Yuefeng WU, Nanshan District Shenzhen, Guangdong (CN); Haifeng GUO, Nanshan District Shenzhen, Guangdong (CN); Fangyu LIU, Nanshan District Shenzhen, Guangdong (CN); Qian CHEN, Nanshan District Shenzhen, Guangdong (CN)

(73) Assignee: Shenzhen MicroBT Electronics Technology Co., Ltd., Nanshan District Shenzhen, Guangdong (CN)

(21) Appl. No.: 18/711,791

(22) PCT Filed: Jan. 9, 2024
(86) PCT No.: PCT/CN2024/071304

§ 371 Date: May 20, 2024

(30) Foreign Application Priority Data
Aug. 3, 2023 (CN) 202310969119.9

(51) Int. Cl. H05K 7/20

(52) U.S. Cl. CPC H05K 7/20763; H05K 7/20718; H05K 7/20909; H05K 7/20927

(57) ABSTRACT

An embodiment of the present application proposes a block chain server and a power supply heat sinking method and apparatus, and a power supply therefor, and a storage medium. The method includes: determining a first component and a second component included in the power supply for the block chain server, where the first component is a component with a service life insensitive to an operating temperature, and the second component is a component with a service life sensitive to the operating temperature; performing heat sinking on the first component in a liquid-cooled manner; and performing heat sinking on the second component in an air-cooled manner.

This application claims priority to Chinese Patent Application No. 2023109691199 entitled “Block Chain Server and Power Supply Heat Sinking Method and Apparatus thereof, and Power Supply, and Storage Medium” filed to China National Intellectual Property Administration on Aug. 3, 2023, the entire content of which is incorporated herein by reference.

### TECHNICAL FIELD

The present application relates generally to the field of technical information, and more particularly relates to a block chain server and a power supply heat sinking method and apparatus thereof, and a power supply, and a storage medium.

### BACKGROUND ART

In general, block chain technology is a brand-new distributed infrastructure and computing approach that uses a block chain-type data structure to verify and store data, uses a distributed node consensus algorithm to generate and update data, uses a cryptography approach to ensure the security of data transmission and access, and uses a smart contract composed of automated script codes to program and operate the data. A block chain network is a decentralized network, which is a peer-to-peer (P2P) network. There is no centralized service and hierarchical structure in the block chain network. Each node is a Peer-to-Peer node, and all nodes provide network services together. The node in the block chain network is both a client and a server.

As the power of the block chain server increases gradually, a previous air-cooled heat sinking method has been difficult to meet heat sinking requirements, and is gradually developing towards a liquid-cooled heat sinking method. Currently, a server power supply with a uniform liquid-cooled heat sinking structure has emerged. When the temperature of a liquid coolant is relatively high, the internal temperature of the power supply will also increase accordingly. However, each constituent component of the power supply has different heat production and heat resistance characteristics. If a uniform liquid-cooled heat sinking method is used, particular constituent components (e.g., components that produce less heat and/or have lower temperature tolerance values) may be adversely affected, thereby affecting the overall life of the power supply.

### SUMMARY

An embodiment of the present application provides a power supply heat sinking method for a block chain server, executed by the block chain server, and including:
determining a first component and a second component included in a power supply for the block chain server, where the first component is a component with a service life insensitive to an operating temperature, and the second component is a component with a service life sensitive to the operating temperature;
performing heat sinking on the first component in a liquid-cooled manner; and
performing heat sinking on the second component in an air-cooled manner.

In some embodiments, the determining the first component and the second component included in a power supply for the block chain server includes:
determining heat production power of constituent components of the power supply;
determining a constituent component with heat production power greater than or equal to a predetermined heat production power threshold value as the first component; and
determining a constituent component with heat production power less than the heat production power threshold value as the second component.

In some embodiments, the determining the first component and the second component included in the power supply for the block chain server includes:
determining temperature coefficients of constituent components of the power supply;
determining a constituent component with a temperature coefficient less than or equal to a predetermined temperature coefficient threshold value as the first component; and
determining a constituent component with a temperature coefficient greater than the temperature coefficient threshold value as the second component.

In some embodiments, the determining the first component and the second component included in the power supply for the block chain server includes:
determining heat production power and temperature coefficients of constituent components of the power supply;
determining a constituent component with a temperature coefficient less than or equal to a predetermined temperature coefficient threshold value and heat production power greater than or equal to a predetermined heat production power threshold value as the first component; and
determining a constituent component with a temperature coefficient greater than the temperature coefficient threshold value and heat production power less than the heat production power threshold value as the second component.

In some embodiments, the performing heat sinking on the first component in the liquid-cooled manner includes:
arranging the first component onto a liquid-cooled plate via a heat-conducting medium; and
the performing heat sinking on the second component in the air-cooled manner includes:
arranging the second component separately from the first component, where the second component has no heat exchange connection with the liquid-cooled plate; and
providing an air-cooled heat sinking channel for the second component.

In some embodiments, the first component includes at least one of:
a field effect transistor; a transformer; an inductor; an insulated gate bipolar transistor; and a rectifier diode; and
the second component includes at least one of:
a controller; and an electrolytic capacitor.

An embodiment of the present application provides a power supply heat sinking apparatus for a block chain server, including:
a determination module, configured to determine a first component and a second component included in a power supply for the block chain server, where the first component is a component with a service life insensitive to an operating temperature, and the second component is a component with a service life sensitive to the operating temperature;
a liquid-cooled heat sinking module, configured to perform heat sinking on the first component in a liquid-cooled manner; and
an air-cooled heat sinking module, configured to perform heat sinking on the second component in an air-cooled manner.

An embodiment of the present application provides a power supply for a block chain server, including:
a first component, a service life of the first component being insensitive to an operating temperature, and the first component being arranged on a liquid-cooled plate, where the liquid-cooled plate is configured to perform heat sinking on the first component in a liquid-cooled manner;
a second component, arranged separately from the first component, the second component having no heat exchange connection with the liquid-cooled plate, and a service life of the second component being sensitive to the operating temperature; and
an air-cooled heat sinking channel, configured to perform heat sinking on the second component in an air-cooled manner.

In some embodiments, the first component and the second component are included in a same functional module of the power supply.

An embodiment of the present application further provides a block chain server, including:
a liquid-cooled plate, the liquid-cooled plate containing a liquid coolant therein;
a chip board, including a plurality of chips, where the chip board has a heat exchange connection with the liquid-cooled plate; and
a control panel;
where the chip board has a signal connection with the control panel via a signal connection interface, and the chip board has an electric power connection with the power supply as described in any one of the embodiments via a power supply connection interface.

An embodiment of the present application further provides a computer-readable storage medium having stored therein a computer-readable instruction, the computer-readable instruction being used for executing the power supply heat sinking method for the block chain server as described in any one of the embodiments.

An embodiment of the present application further provides a computer program product, including a computer program, where the computer program is stored in a computer-readable storage medium; and a processor of a server, when reading the computer program from the computer-readable storage medium, executes the computer program such that the server executes the power supply heat sinking method for the block chain server as described in any embodiment of the present application.

### BRIEF DESCRIPTION OF THE DRAWINGS

FIG. 1 is a schematic diagram of a power supply heat sinking structure of a block chain server in the related art.

FIG. 2 is a flowchart of a power supply heat sinking method for a block chain server according to an implementation of the present application.

FIG. 3 is a side view of a power supply heat sinking structure of a block chain server according to an implementation of the present application.

FIG. 4 is a top view of a power supply heat sinking structure of a block chain server according to an implementation of the present application.

FIG. 5 is a structural diagram of a power supply heat sinking apparatus for a block chain server according to an implementation of the present application.

FIG. 6 is a structural diagram of a power supply heat sinking apparatus for a block chain server with a memory-processor architecture according to an implementation of the present application.

FIG. 7 is a structural diagram of a block chain server according to an implementation of the present application.

### DETAILED DESCRIPTION OF THE INVENTION

For simplicity and clarity of description, the solutions of the present application are set forth below by describing several representative implementations. Numerous details of the implementations are merely intended to facilitate an understanding of the solutions of the present application. However, it is obvious that the technical solution of the present application can be implemented beyond these details. To avoid unnecessarily obscuring the solutions of the present application, some implementations have not been described in details, but rather have been given a framework. Hereinafter, “including” refers to “including but not limited to”, and “according to” refers to “at least according to, but not limited to only according to”. In view of language habits of Chinese, when the number of a component is not specifically indicated below, it is meant that the number of the component may be one or more, or may be understood as at least one.

The temperature of a liquid coolant (e.g., water) obtained after performing heat sinking on a block chain server usually is relatively high. Therefore, the liquid coolant obtained after the heat sinking can be used for providing a heat source for a heating system, an industrial application or the like to realize secondary utilization of energy.

In the related art, when the temperature of the liquid coolant is relatively high, the internal temperature of a server power supply will also increase, thereby affecting a service life of the server power supply. Moreover, currently, a uniform liquid-cooled heat sinking manner is generally employed for each constituent component in a power supply for the block chain server. For particular constituent components (e.g., components that produce less heat and/or have lower temperature tolerance values), this uniform liquid-cooled manner may adversely affect these particular constituent components, thereby affecting an overall life of the power supply.

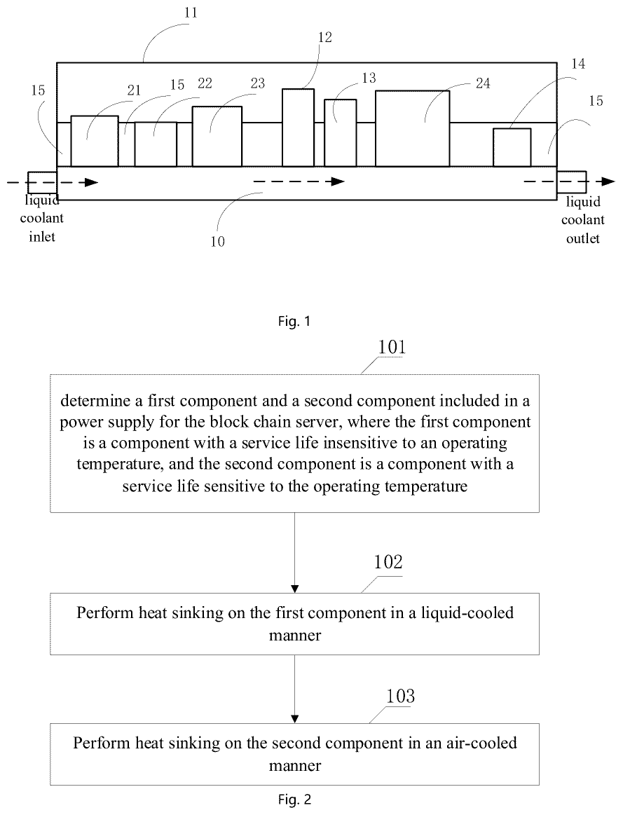

An exemplary heat sinking structure of a power supply for a block chain server in the related art will be described below in conjunction with FIG. 1. FIG. 1 is a schematic diagram of a power supply heat sinking structure of a block chain server in the related art. In FIG. 1, a power supply housing 11 includes a plurality of constituent components, specifically including: a filter 21, an inductor 22, a metal oxide semiconductor field effect transistor (MOSFET) 23, a controller chip 12, an electrolytic capacitor 13, a transformer 24 and a sampling chip 14. The filter 21, the inductor 22, the MOSFET 23, the controller chip 12, the electrolytic capacitor 13, the transformer 24 and the sampling chip 14 are each poured onto a liquid-cooled plate 10 via respective heat-conducting glue 15, and have a heat exchange connection with the liquid-cooled plate 10 respectively, thereby forming a uniform liquid-cooled heat sinking manner.

However, for components that produce less heat and/or have lower temperature tolerance values (e.g., the controller chip 12, the electrolytic capacitor 13, and the sampling chip 14), this uniform liquid-cooled heat sinking manner has an adverse effect, and may affect service lives of the components. For example, the temperature of a liquid coolant at an inlet of the liquid-cooled plate 10 may be relatively high (e.g., 70° C.), and a desired operating temperature of the electrolytic capacitor 13 may be 20° C. to 30° C. At this time, the temperature of the electrolytic capacitor 13 in heat exchange with the liquid-cooled plate 10 will be undesirably significantly increased. If the temperature of the electrolytic capacitor 13 is increased by 10° C., the service life of the electrolytic capacitor 13 is shortened to about half of an original service life, thereby affecting the service life of the electrolytic capacitor 13, and further affecting the service life of the server power supply and the entire server.

Based on this, the constituent components in the power supply can be classified, based on characteristics of each constituent component inside the power supply, into a first category and a second category: components with a service life insensitive to an operating temperature; and components with a service life sensitive to the operating temperature. For the first category of components, heat sinking is performed in a liquid-cooled manner, thereby not only ensuring heat sinking performance of the components, but also fully increasing the temperature of the liquid coolant at an outlet to facilitate subsequent comprehensive utilization of heat energy. For the second category of components, heat sinking is performed in an air-cooled manner independent of the liquid-cooled manner. That is, the second category of components no longer exchange heat with the liquid-cooled plate, but performs separate heat sinking in an air-cooled manner. Compared with the uniform liquid-cooled heat sinking manner, the temperature of the second category of components can be significantly reduced, thereby prolonging service lives and improving the stability of the second category of components.

FIG. 2 is a flowchart of a power supply heat sinking method for a block chain server provided by an embodiment of the present application. As shown in FIG. 2, the method includes:
step 101: determine a first component and a second component included in a power supply for the block chain server, where the first component is a component with a service life insensitive to an operating temperature, and the second component is a component with a service life sensitive to the operating temperature.

Heat productivity of the component in the power supply for the block chain server during operation has an increasing relationship with heat production power of the component. Considering that a component with high heat production power generally has relatively high temperature tolerance, the heat production power can be directly used as a criterion for distinguishing the first component from the second component.

In some embodiments, step 101 includes: determining heat production power of constituent components of the power supply; determining a constituent component with heat production power greater than or equal to a predetermined heat production power threshold value as the first component; and determining a constituent component with heat production power less than the heat production power threshold value as the second component.

For example, it is assumed that the constituent components of the power supply include component A, component B, component C, component D, component E, and component F, and the heat production power threshold values can be determined based on empirical values or test results. In some embodiments, the heat production power threshold value is adjustable. The heat production power of each of the component A, the component B, the component C, the component D, the component E, and the component F can be determined by looking up a table or performing a test. It is assumed that the determined heat production power of each of the component A, the component B, and the component C is greater than or equal to the heat production power threshold value, while the heat production power of each of the component D, the component E, and the component F is less than the heat production power threshold value.

By comparing the heat production power of each of the component A, the component B, the component C, the component D, the component E, and the component F with the heat production power threshold value, each component (i.e., the component A, the component B, and the component C) with the heat production power greater than or equal to the heat production power threshold value is determined as a first component, and each component (i.e., the component D, the component E, and the component F) with heat production power less than the heat production power threshold value is determined as a second component.

In an embodiment of the present application, a first component is distinguished from a second component by directly using heat production power, which enables a user to determine the heat production power of each component by simply looking up a table or performing a test, and constituent components of a power supply can be divided into two major categories according to the heat production power, which has the advantage of convenient implementation.

A temperature coefficient of the component in the power supply for the block chain server can be used as a measure of temperature tolerance of the component. The temperature coefficient is a rate at which a physical property of the component changes with temperature. For example, when a device is a capacitor, the temperature coefficient is a ratio of a change value of capacitance to nominal capacitance at this temperature for every 1° C. change in temperature within a given temperature interval; and when the device is an inductor, the temperature coefficient is a ratio of a change value of inductance to nominal inductance at this temperature for every 1° C. change in temperature within a given temperature interval. For a component with a smaller temperature coefficient, a rate of change in its physical property with a temperature change is relatively low. Therefore, the component generally has better temperature tolerance, and its service life is less affected by the temperature change.

In some embodiments of the present application, step 101 includes: determining temperature coefficients of constituent components of the power supply; determining a constituent component with a temperature coefficient less than or equal to a predetermined temperature coefficient threshold value as the first component; and determining a constituent component with a temperature coefficient greater than the temperature coefficient threshold value as the second component.

For example, it is assumed that the constituent components of the power supply include component A, component B, component C, component D, component E, and component F, and the temperature coefficient threshold values can be determined based on empirical values or test results. In some embodiments, the temperature coefficient threshold value is adjustable. A temperature coefficient of each of the component A, the component B, the component C, the component D, the component E, and the component F can be determined by looking up a table or performing a test. It is assumed that the determined temperature coefficients of the component A, the component B, the component C, and the component D are greater than the temperature coefficient threshold value, while the temperature coefficients of the component E and the component F are less than or equal to the temperature coefficient threshold value.

By comparing the temperature coefficient of each of the component A, the component B, the component C, the component D, the component E, and the component F with the temperature coefficient threshold value, each component (i.e., the component A, the component B, the component C, and the component D) with its own temperature coefficient greater than the temperature coefficient threshold value is determined as a second component, and each component (i.e., the component E and the component F) with its own temperature coefficient less than the heat production power threshold value is determined as a first component.

In an embodiment of the present application, a first component is distinguished from a second component by directly using temperature coefficients, which enables a user to determine the temperature coefficient of each component by simply looking up a table or performing a test, and constituent components of a power supply can be divided into two major categories according to the temperature coefficient, which has the advantage of convenient implementation as well.

In some embodiments of the present application, a first component can be distinguished from a second component by jointly using heat production power for characterizing heat productivity during operation and a temperature coefficient for characterizing temperature tolerance.

In an implementation, step 101 includes: determining heat production power and temperature coefficients of constituent components of the power supply; determining a constituent component with a temperature coefficient less than or equal to a temperature coefficient threshold value and heat production power greater than or equal to a predetermined heat production power threshold value as the first component; and determining a constituent component with a temperature coefficient greater than the temperature coefficient threshold value and heat production power less than the heat production power threshold value as the second component.

For example, it is assumed that the constituent components of the power supply include component A, component B, component C, component D, component E, and component F, and the temperature coefficient threshold values and the heat production coefficient threshold values can be determined based on empirical values or test results. In some embodiments, both the temperature coefficient threshold value and the heat production coefficient threshold value are adjustable. A temperature coefficient and heat production power of each of the component A, the component B, the component C, the component D, the component E, the component D, the component E and the component F can be determined by looking up a table or performing a test.

It is assumed that the determined heat production power of each of the component A, the component B, and the component C is less than the heat production power threshold value, while the heat production power of each of the component D, the component E, and the component F is greater than or equal to the heat production power threshold value. It is assumed that the determined temperature coefficients of the component A, the component B, the component C, and the component D are greater than the temperature coefficient threshold value, while the temperature coefficients of the component E and the component F are less than or equal to the temperature coefficient threshold value.

The temperature coefficient of each of the component A, the component B, the component C, the component D, the component E, and the component F is compared with the temperature coefficient threshold value, and the heat production power of each of the component A, the component B, the component C, the component D, the component E, and the component F is compared with the heat production power threshold value. Each component (i.e., the component E and the component F) with its own temperature coefficient less than or equal to the temperature coefficient threshold value and its own heat production power greater than or equal to the heat production power threshold value is determined as a first component. Each component (i.e., the component A, the component B, and the component C) with its own temperature coefficient greater than the temperature coefficient threshold value and its own heat production power less than the heat production power threshold value is determined as a second component. For a constituent component (e.g., the component D) which cannot be classified into the first component and the second component, heat sinking can be performed in a liquid-cooled manner or in an air-cooled manner, which will not be limited by the implementations of the present application.

In such implementations, a first component is distinguished from a second component by jointly using heat production power and temperature coefficients, and thus, constituent components of a power supply can be more accurately classified into two main categories: the first component and the second component.

Step 102: Perform heat sinking on the first component in a liquid-cooled manner.

Step 103: Perform heat sinking on the second component in an air-cooled manner.

In the flow shown in FIG. 1, there is no particular requirement for the order in which step 102 and step 103 are performed. That is, step 102 may be performed before step 103. Alternatively, step 103 may be performed before step 102. Alternatively, step 102 and step 103 are performed simultaneously.

In some embodiments of the present application, a first component and a second component are included in a same functional module of a power supply. It can be seen that after the implementations of the present application are applied, with regard to each constituent component with different characteristics inside the power supply, even if different components in a same functional module, different heat sinking manners can be employed, thereby achieving refined heat sinking, and prolonging the service life and improving the stability of the second component.

For example, the power supply typically includes a DC-DC functional module. In the related art, a same liquid-cooled heat sinking manner is employed for all components (e.g., a filter capacitor and a transformer) in a DC-DC functional module. After the implementations of the present application are applied, the filter capacitor can be determined as the second component and heat sinking is performed in an air-cooled manner, and the transformer can be determined as the first component and heat sinking is performed in a liquid-cooled manner, thus achieving refined heat sinking in the functional module, and further prolonging the service life and improving the stability of the second component.

In some embodiments of the present application, step 102 includes: arranging the first component onto a liquid-cooled plate via a heat-conducting medium; and step 102 includes: arranging the second component separately from the first component, where the second component has no heat exchange connection with the liquid-cooled plate; and providing an air-cooled heat sinking channel for the second component. For example, the heat-conducting medium may be heat-conducting glue. It can be seen that transfer of heat produced by the first component to the second component can be avoided by arranging the second component separately from the first component, thereby preventing the temperature of the second component from being undesirably increased.

In an implementation, the first component includes at least one of: a field effect transistor (FET); a transformer; an inductor; an insulated gate bipolar transistor (IGBT); a rectifier diode and the like; and the second component includes at least one of: a controller chip; an electrolytic capacitor; a sampling chip; a drive chip and the like.

For example, the FET can be implemented as a junction field effect transistor (JFET) and a metal-oxide-semiconductor field-effect-transistor (MOSFET); the controller chip can be implemented as a digital signal processing (DSP) chip; the sampling chip can be implemented as a voltage sampling chip or a current sampling chip and the like.

Specific examples of the first component and the second component are described in the above embodiments. It will be appreciated by those skilled in the art that such descriptions are exemplary only and are not intended to limit the scope of protection of the implementations of the present application.

In an implementation of the present invention, a first component and a second component included in a power supply for a block chain server are determined, where the first component is a component with a service life insensitive to an operating temperature, and the second component is a component with a service life sensitive to the operating temperature; heat sinking is performed on the first component in a liquid-cooled manner; and heat sinking is performed on the second component in an air-cooled manner. It can be seen that overall optimization of a heat sinking effect and an energy utilization effect can be achieved by using different heat sinking manners for each constituent component with different characteristics inside the power supply. For example, for the component with the service life sensitive to the operating temperature, heat sinking in an air-cooled manner can significantly reduce the operating temperature, and can improve the service life of the component. For the component with the service life insensitive to the operating temperature, the liquid-cooled manner not only can ensure heat sinking performance of the component, but also can fully increase the temperature of a liquid coolant at an outlet to facilitate subsequent comprehensive utilization of heat energy.

It will be illustrated with a power supply heat sinking structure of an implementation of the present application below.

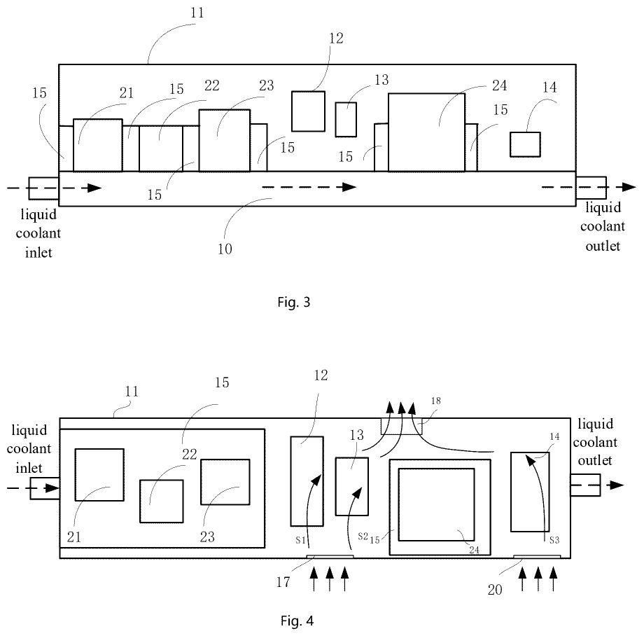

FIG. 3 is a side view of a power supply heat sinking structure of a block chain server according to an implementation of the present application. FIG. 4 is a top view of a power supply heat sinking structure of a block chain server according to an implementation of the present application.

As seen from FIGS. 3 and 4, a power supply housing 11 includes a plurality of constituent components, specifically including: a filter 21, an inductor 22, an MOSFET 23, a controller chip 12, an electrolytic capacitor 13, a transformer 24, and a sampling chip 14.

The filter 21, the inductor 22, the MOSFET 23 and the transformer 24 are classified as a first component with a service life insensitive to an operating temperature. Specific classification criteria corresponding to the first component may include any one of: (1): heat production power is greater than or equal to a predetermined heat production power threshold value; (2): a temperature coefficient is less than or equal to a temperature coefficient threshold value; and (3): the temperature coefficient is less than or equal to the temperature coefficient threshold value and the heat production power is greater than or equal to the heat production power threshold value.

The controller chip 12, the electrolytic capacitor 13 and the sampling chip 14 are classified as a second component with a service life sensitive to the operating temperature. Specific classification criteria corresponding to the second component may include any one of: (1): heat production power is less than a predetermined heat production power threshold value; (2): a temperature coefficient is greater than a predetermined temperature coefficient threshold value; and (3): the heat production power is less than the predetermined heat production power threshold value and the temperature coefficient is greater than the predetermined temperature coefficient threshold value.

The filter 21, the inductor 22, the MOSFET 23 and the transformer 24 are each poured onto a liquid-cooled plate 10 via respective heat-conducting glue 15, and each have a heat exchange connection with the liquid-cooled plate 10. With the liquid-cooled plate 10, liquid-cooled heat sinking can be performed on the filter 21, the inductor 22, the MOSFET 23 and the transformer 24.

Any of the controller chip 12, the electrolytic capacitor 13, and the sampling chip 14 is not in thermal contact with any of the filter 21, the inductor 22, the MOSFET 23, and the transformer 24. Moreover, the controller chip 12, the electrolytic capacitor 13, and the sampling chip 14 have respective air-cooled heat sinking channels. For example, air enters the housing 11 via an inlet 17, and flows through the controller chip 12 in the direction of arrow S1 to perform heat sinking on the controller chip 12. The air enters the housing 11 via the inlet 17, and flows through the electrolytic capacitor 13 in the direction of arrow S2 to perform heat sinking on the electrolytic capacitor 13; and the air enters the housing 11 via the inlet 20, and flows through the sampling chip 14 in the direction of arrow S3 to perform heat sinking on the sampling chip 14. Moreover, after being heated, air flowing through each air-cooled heat sinking channel is uniformly discharged out of the housing 11 via a fan 18.

It can be seen that the controller chip 12, the electrolytic capacitor 13 and the sampling chip 14 do not have the heat exchange connection with the liquid-cooled plate 10 in comparison with that of a uniform liquid-cooled heat sinking manner in the related art, thereby preventing the controller chip 12, the electrolytic capacitor 13 and the sampling chip 14 from being undesirably heated. Moreover, the controller chip 12, the electrolytic capacitor 13, and the sampling chip 14 are each not in contact with the first components (the filter 21, the inductor 22, the MOSFET 23, and the transformer 24), thereby preventing them from being heated by the first component. Also, heat-conducting glue 15 for each of the controller chip 12, the electrolytic capacitor 13, and the sampling chip 14 is omitted.

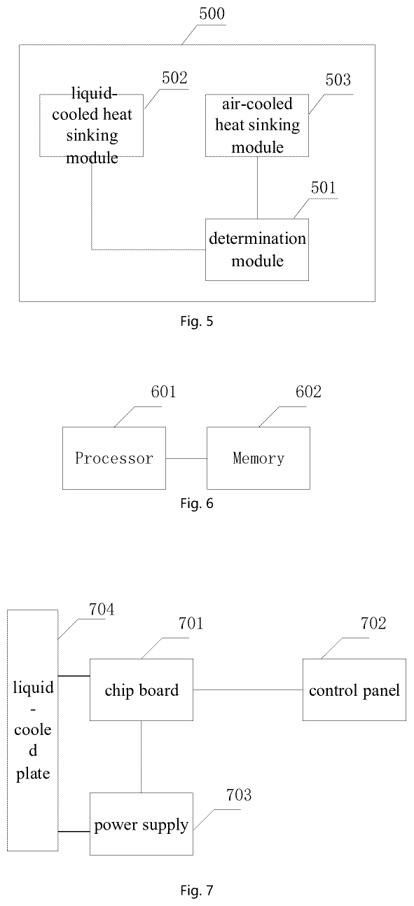

FIG. 5 is a structural diagram of a power supply heat sinking apparatus for a block chain server according to an embodiment of the present application. As shown in FIG. 5, a power supply heat sinking apparatus 500 includes:
a determination module 501, configured to determine a first component and a second component included in a power supply for the block chain server, where the first component is a component with a service life insensitive to an operating temperature, and the second component is a component with a service life sensitive to the operating temperature;
a liquid-cooled heat sinking module 502, configured to perform heat sinking on the first component in a liquid-cooled manner; and
an air-cooled heat sinking module 503, configured to perform heat sinking on the second component in an air-cooled manner.

In some embodiments, the determination module 501 is configured to determine heat production power of constituent components of a power supply; determine a constituent component with heat production power greater than or equal to a predetermined heat production power threshold value as a first component; and determine a constituent component with heat production power less than the heat production power threshold value as a second component.

In some embodiments, the determination module 501 is configured to determine temperature coefficients of constituent components of a power supply; determine a constituent component with a temperature coefficient less than or equal to a predetermined temperature coefficient threshold value as a first component; and determine a constituent component with a temperature coefficient greater than the temperature coefficient threshold value as a second component.

In some embodiments, the determination module 501 is configured to determine heat production power and temperature coefficients of constituent components of the power supply; determine a constituent component with a temperature coefficient less than or equal to a predetermined temperature coefficient threshold value and heat production power greater than or equal to a predetermined heat production power threshold value as a first component; and determine a constituent component with a temperature coefficient greater than the temperature coefficient threshold value and heat production power greater than the heat production power threshold value as a second component.

In some embodiments, the liquid-cooled heat sinking module 502 is configured to arrange a first component onto a liquid-cooled plate via a heat-conducting medium; the air-cooled heat sinking module 503 is configured to arrange the second component separately from the first component, where the second component has no heat exchange connection with the liquid-cooled plate; and provide an air-cooled heat sinking channel for the second component.

An implementation of the present application further provides a power supply for a block chain server. The power supply includes: a first component, a second component, and an air-cooled heat sinking channel, where the service life of the first component is insensitive to an operating temperature, the first component is arranged on a liquid-cooled plate, and the liquid-cooled plate executes heat sinking on the first component in a liquid-cooled manner; the second component is arranged separately from the first component, the second component has no heat exchange connection with the liquid-cooled plate, and the service life of the second component is sensitive to the operating temperature; and the air-cooled heat sinking channel is configured to execute heat sinking on the second component in an air-cooled manner.

In an implementation, the first component and the second component are included in a same functional module of the power supply, thereby achieving refined heat sinking within the functional module.

FIG. 6 is a structural diagram of a power supply heat sinking apparatus for a block chain server with a memory-processor architecture according to an implementation of the present application.

As shown in FIG. 6, the power supply heat sinking apparatus for the block chain server includes: a processor 601 and a memory 602. The memory 602 has stored therein an application program executable by the processor 601 for causing the processor 601 to execute the power supply heat sinking method for the block chain server in any one of the embodiments. The memory 602 can be implemented as various storage media such as an electrically erasable programmable read-only memory (EEPROM), a flash memory, and a programmable read-only memory (PROM). The processor 601 can be implemented to include one or more central processing units or one or more field programmable gate arrays, where the field programmable gate array integrates one or more central processing unit cores. Specifically, the central processor or central processor core can be implemented as a CPU, an MCU or a digital signal processor (DSP).

An implementation of the present application further provides a block chain server. FIG. 7 is a structural diagram of a block chain server according to an implementation of the present application. As shown in FIG. 7, the block chain server includes:
a liquid-cooled plate 704, where the liquid-cooled plate 704 contains a liquid coolant therein;
a chip board 701, where the chip board 701 has a heat exchange relationship with the liquid-cooled plate 704 (for example, the liquid-cooled plate 704 is in direct contact with the chip board 701 or in contact with the chip board 701 via a heat-conducting medium to achieve heat exchange); and
a control panel 702, including: a memory and a processor, where the memory may have stored therein an application program executable by a processor for causing the processor to execute the power supply heat sinking method for the block chain server in any one of the embodiments; the chip board 701 forms a signal connection with the control panel 702 via a signal connection interface, and the chip board 701 forms an electric power connection with the power supply 703 as described above via a power supply connection interface.

It should be noted that not all steps and modules in the above-mentioned flowcharts and structural diagrams are necessary, and some of the steps or modules may be omitted according to actual needs. The order in which all the steps are executed is not fixed, and can be adjusted as needed. The division of various modules is merely to facilitate the description of the functional division employed. When actually implemented, one module can be implemented as being divided into a plurality of modules, the functions of the plurality of modules can also be implemented by the same module, and these modules can be located in the same device or in different devices. Hardware modules in each implementation can be implemented mechanically or electronically. For example, one hardware module may include a specially designed permanent circuit or logic device (e.g., a dedicated processor such as an FPGA or an ASIC) for completing a particular operation. The hardware module may also include a programmable logic device or circuit (e.g., including a general purpose processor or other programmable processors) temporarily configured by software to execute particular operations. As for whether to implement the hardware module in a mechanical manner, or with the dedicated permanent circuit, or with the temporarily configured circuit (e.g., configured by software), it can be determined in consideration of cost and time.

The present application further provides a machine-readable storage medium, storing instructions for causing a machine to execute the method as described in the present application. Specifically, a system or apparatus equipped with a storage medium may be provided, on which a software program code implementing the functions of any implementation of the above-mentioned embodiments is stored, and a computer (or a CPU or an MPU) of the system or the apparatus is made to read out and execute the program code stored in the storage medium. Furthermore, some or all of actual operations can be completed by an operating system and the like operating on the computer by a program code-based instruction. The program code read out from the storage medium may also be written into a memory provided in an expansion board inserted into the computer or written into a memory provided in an expansion unit connected to the computer, and then the program code-based instruction causes a CPU and the like installed on the expansion board or the expansion unit to execute some or all of the actual operations, thereby implementing the functions of any of the above-mentioned implementations. Implementations of storage media used for providing program codes include floppy disks, hard disks, magneto-optical disks, optical disks (e.g., CD-ROM, CD-R, CD-RW, DVD-ROM, DVD-RAM, DVD-RW, and DVD+RW), magnetic tapes, non-volatile memory cards, and ROM. Optionally, the program code can be downloaded from a block chain server computer or cloud via a communication network.

Herein, “schematic” represents “serving as an example, instance, or illustration”, and any illustration and implementation described herein as “schematic” should not be construed as a more preferred or advantageous technical solution. In order to simplify the drawings, each figure only schematically represents portions relevant to the present application, and do not represent an actual structure of its product. In addition, in order to make the drawings concise and easy to understand, in some drawings, only one of components having the same structure or function is schematically illustrated, or only one of them is numbered. Herein, “one” does not denote limiting the number of the relevant portions of the present application to “only one”, and “one” does not denote excluding the situation where the number of the relevant parts of the present application is “more than one”. Herein, “upper”, “lower”, “front”, “back”, “left”, “right”, “inner”, “outer” and the like are used merely to denote relative positional relationships between the relevant portions, and do not define the absolute positions of these relevant portions.

The foregoing is merely a preferred embodiment of the present application, and is not intended to limit the scope of protection of the present application. Any modifications, equivalent substitutions, improvements and the like made within the spirit and principles of the present application shall be included within the scope of protection of the present application.

1-12. (canceled)

13. A power supply heat sinking method for a block chain server, executed by the block chain server, and comprising:
determining a first component and a second component comprised in a power supply for the block chain server, wherein the first component is a component with a service life insensitive to an operating temperature, and the second component is a component with a service life sensitive to the operating temperature;
performing heat sinking on the first component in a liquid-cooled manner; and
performing heat sinking on the second component in an air-cooled manner.

14. The method according to claim 13, wherein the determining the first component and the second component comprised in the power supply for the block chain server comprises:
determining heat production power of constituent components of the power supply;
determining a constituent component with heat production power greater than or equal to a predetermined heat production power threshold value as the first component; and
determining a constituent component with heat production power less than the heat production power threshold value as the second component.

15. The method according to claim 13, wherein the determining the first component and the second component comprised in the power supply for the block chain server comprises:
determining temperature coefficients of constituent components of the power supply;
determining a constituent component with a temperature coefficient less than or equal to a predetermined temperature coefficient threshold value as the first component; and
determining a constituent component with a temperature coefficient greater than the temperature coefficient threshold value as the second component.

16. The method according to claim 13, wherein the determining the first component and the second component comprised in the power supply for the block chain server comprises:
determining heat production power and temperature coefficients of constituent components of the power supply;
determining a constituent component with a temperature coefficient less than or equal to a predetermined temperature coefficient threshold value and heat production power greater than or equal to a predetermined heat production power threshold value as the first component; and
determining a constituent component with a temperature coefficient greater than the temperature coefficient threshold value and heat production power less than the heat production power threshold value as the second component.

17. The method according to claim 13, wherein the performing heat sinking on the first component in the liquid-cooled manner comprises:
arranging the first component onto a liquid-cooled plate via a heat-conducting medium; and
wherein the performing heat sinking on the second component in the air-cooled manner comprises:
arranging the second component separately from the first component, wherein the second component has no heat exchange connection with the liquid-cooled plate; and
providing an air-cooled heat sinking channel for the second component.

18. The method according to claim 14, wherein the performing heat sinking on the first component in the liquid-cooled manner comprises:
arranging the first component onto a liquid-cooled plate via a heat-conducting medium; and
wherein the performing heat sinking on the second component in the air-cooled manner comprises:
arranging the second component separately from the first component, wherein the second component has no heat exchange connection with the liquid-cooled plate; and
providing an air-cooled heat sinking channel for the second component.

19. The method according to claim 15, wherein the performing heat sinking on the first component in the liquid-cooled manner comprises:
arranging the first component onto a liquid-cooled plate via a heat-conducting medium; and
wherein the performing heat sinking on the second component in the air-cooled manner comprises:
arranging the second component separately from the first component, wherein the second component has no heat exchange connection with the liquid-cooled plate; and
providing an air-cooled heat sinking channel for the second component.

20. The method according to claim 16, wherein the performing heat sinking on the first component in the liquid-cooled manner comprises:
arranging the first component onto a liquid-cooled plate via a heat-conducting medium; and
wherein the performing heat sinking on the second component in the air-cooled manner comprises:
arranging the second component separately from the first component, wherein the second component has no heat exchange connection with the liquid-cooled plate; and
providing an air-cooled heat sinking channel for the second component.

21. The method according to claim 13, wherein the first component comprises at least one of:
a field effect transistor; a transformer; an inductor; an insulated gate bipolar transistor; and a rectifier diode; and
the second component comprises at least one of: a controller chip; an electrolytic capacitor; a sampling chip; and a drive chip.

22. The method according to claim 14, wherein the first component comprises at least one of:
a field effect transistor; a transformer; an inductor; an insulated gate bipolar transistor; and a rectifier diode; and
the second component comprises at least one of: a controller chip; an electrolytic capacitor; a sampling chip; and a drive chip.

23. The method according to claim 15, wherein the first component comprises at least one of:
a field effect transistor; a transformer; an inductor; an insulated gate bipolar transistor; and a rectifier diode; and
the second component comprises at least one of: a controller chip; an electrolytic capacitor; a sampling chip; and a drive chip.

24. The method according to claim 16, wherein the first component comprises at least one of:
a field effect transistor; a transformer; an inductor; an insulated gate bipolar transistor; and a rectifier diode; and
the second component comprises at least one of: a controller chip; an electrolytic capacitor; a sampling chip; and a drive chip.

25. A block chain server, comprising:
a liquid-cooled plate, the liquid-cooled plate containing a liquid coolant therein;
a chip board, comprising a plurality of chips, wherein the chip board has a heat exchange connection with the liquid-cooled plate; and
a control panel comprising a memory and a processor;
wherein the chip board has a signal connection with the control panel via a signal connection interface, and the chip board has an electric power connection with a power supply for the block chain server via a power supply connection interface;
wherein the memory has stored therein an application program executable by a processor for causing the processor to execute:
determining a first component and a second component comprised in a power supply for the block chain server, wherein the first component is a component with a service life insensitive to an operating temperature, and the second component is a component with a service life sensitive to the operating temperature;
performing heat sinking on the first component in a liquid-cooled manner; and
performing heat sinking on the second component in an air-cooled manner.

26. The block chain server according to claim 25, wherein the application program is executed by the processor for causing the processor to execute:
determining heat production power of constituent components of the power supply;
determining a constituent component with heat production power greater than or equal to a predetermined heat production power threshold value as the first component; and
determining a constituent component with heat production power less than the heat production power threshold value as the second component.

27. The block chain server according to claim 25, wherein the application program is executed by the processor for causing the processor to execute:
determining temperature coefficients of constituent components of the power supply;
determining a constituent component with a temperature coefficient less than or equal to a predetermined temperature coefficient threshold value as the first component; and
determining a constituent component with a temperature coefficient greater than the temperature coefficient threshold value as the second component.

28. The block chain server according to claim 25, wherein the application program is executed by the processor for causing the processor to execute:
determining heat production power and temperature coefficients of constituent components of the power supply;
determining a constituent component with a temperature coefficient less than or equal to a predetermined temperature coefficient threshold value and heat production power greater than or equal to a predetermined heat production power threshold value as the first component; and
determining a constituent component with a temperature coefficient greater than the temperature coefficient threshold value and heat production power less than the heat production power threshold value as the second component.

29. The block chain server according to claim 25, wherein the application program is executed by the processor for causing the processor to execute:
arranging the first component onto a liquid-cooled plate via a heat-conducting medium;
arranging the second component separately from the first component, wherein the second component has no heat exchange connection with the liquid-cooled plate; and
providing an air-cooled heat sinking channel for the second component.

30. The block chain server according to claim 25, wherein the first component comprises at least one of:
a field effect transistor; a transformer; an inductor; an insulated gate bipolar transistor; and a rectifier diode; and
the second component comprises at least one of: a controller chip; an electrolytic capacitor; a sampling chip; and a drive chip.

31. A computer-readable storage medium having stored therein a computer-readable instruction, the computer-readable instruction being used for executing the power supply heat sinking method for the block chain server, the method comprising:
determining a first component and a second component comprised in a power supply for the block chain server, wherein the first component is a component with a service life insensitive to an operating temperature, and the second component is a component with a service life sensitive to the operating temperature;
performing heat sinking on the first component in a liquid-cooled manner; and
performing heat sinking on the second component in an air-cooled manner.

32. The computer-readable storage medium according to claim 31, determining the first component and the second component comprised in the power supply for the block chain server comprises:
determining heat production power of constituent components of the power supply;
determining a constituent component with heat production power greater than or equal to a predetermined heat production power threshold value as the first component; and
determining a constituent component with heat production power less than the heat production power threshold value as the second component.
